(19) United States
(12) Patent Application Publication
(10) Pub. No.: US 2024/0213993 A1
(43) Pub. Date: Jun. 27, 2024

(54) APPARATUS FOR ANALOG-TO-DIGITAL CONVERSION, RECEIVER, BASE STATION, MOBILE DEVICE AND METHOD FOR ANALOG-TO-DIGITAL CONVERSION

(71) Applicant: Intel Corporation, Santa Clara, CA (US)

(72) Inventors: Albert MOLINA, Novelda (ES); Kameran AZADET, San Ramon, CA (US); Matteo CAMPONESCHI, Villach (AT); Martin CLARA, Santa Clara, CA (US)

(21) Appl. No.: 18/145,108

(22) Filed: Dec. 22, 2022

(51) Int. Cl. H03M 1/06

(52) U.S. Cl. CPC H03M 1/0604

(57) ABSTRACT

Provided is an apparatus for analog-to-digital conversion. The apparatus comprises a plurality of first analog-to-digital converter, ADC, cores configured to receive an analog input signal and to generate respective first digital data based on the analog input signal. Further, the apparatus comprises a second ADC core configured to receive the analog input signal and to generate second digital data based on the analog input signal. In addition, the apparatus comprises a plurality of correction circuits each coupled to a respective one of the plurality of first ADC cores, wherein the plurality of correction circuits is configured to receive the second digital data and to modify the respective first digital data based on the second digital data.

### BACKGROUND

In analog-to-digital conversion, electrical components used for this purpose, such as comparators, buffers or the like, may impair signal quality of the conversed digital output. For example, such electrical components may suffer from noise, such as flicker noise or the like, around different frequencies.

Hence, there may be a demand for improved analog-to-digital conversion.

### BRIEF DESCRIPTION OF THE FIGURES

Some examples of apparatuses and/or methods will be described in the following by way of example only, and with reference to the accompanying figures, in which

FIG. 1 illustrates a first example of an apparatus for analog-to-digital conversion;

FIG. 2 illustrates a second example of an apparatus for analog-to-digital conversion;

FIG. 3 illustrates a third example of an apparatus for analog-to-digital conversion;

FIG. 4 illustrates a fourth example of an apparatus for analog-to-digital conversion;

FIG. 5 illustrates a fifth example of an apparatus for analog-to-digital conversion;

FIG. 6 illustrates in a diagram an exemplary noise spectral density caused in analog-to-digital conversion;

FIG. 7 illustrates in a diagram an exemplary noise spectral density caused in analog-to-digital conversion;

FIG. 8 illustrates in a diagram an exemplary spectrum of an apparatus for analog-to-digital conversion;

FIG. 9 illustrates an example of a base station;

FIG. 10 illustrates an example of a mobile device; and

FIG. 11 illustrates in a flowchart an example of a method for analog-to-digital conversion.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

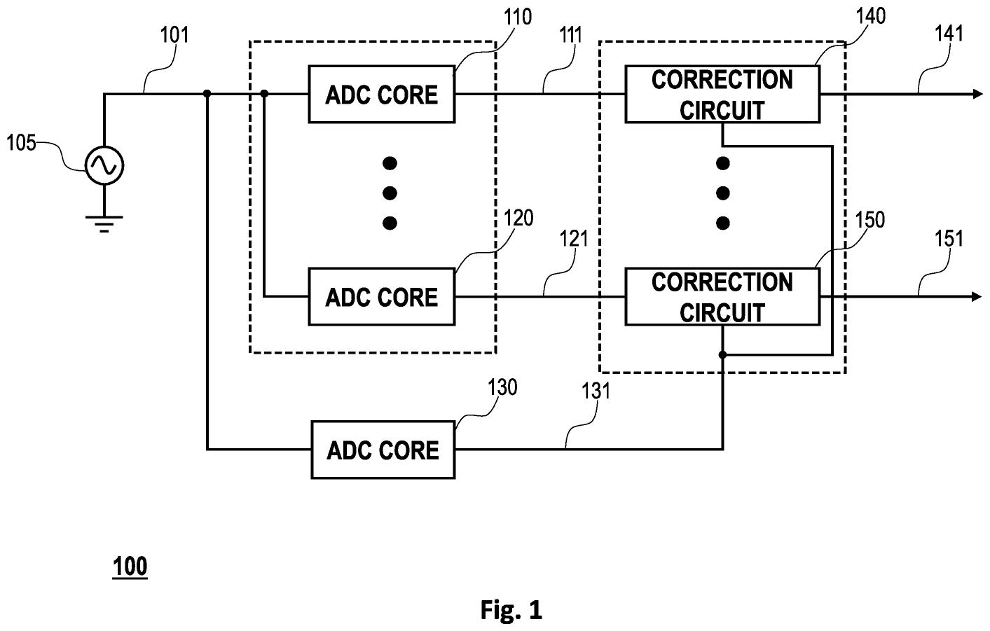

FIG. 1 illustrates an exemplary apparatus 100 for analog-to-digital conversion. The apparatus 100 is configured to convert an analog input signal 101 that may be provided by a signal source 105. For illustration purposes only, FIG. 1 illustrates the signal source 105 as an oscillator. However, it is noted that any circuitry may provide the analog input signal 101 to the apparatus 100. Further, it is noted that the signal source 105 may be provided separately from or together with the apparatus 100.

The apparatus 100 comprises a plurality of first analog-to-digital converter (ADC) cores 110, 120 configured to receive the analog input signal 101 and to generate respective first digital data 111, 121 based on the analog input signal 101. It is noted that although FIG. 1 illustrates only two first ADC cores 110, 120, the number of first ADC cores is not limited herein and the plurality of first ADC cores may comprise more than two. In general, the plurality of first ADC cores may comprise N first ADC cores with N>1. Each of the plurality of first ADC cores, in this example the first ADC cores 110, 120, is configured to receive the analog input signal 101. It is noted that although FIG. 1 illustrates the first ADC cores 110, 120 to directly receive the analog input signal 101 from the signal source 105, further elements, such as a buffer, a circuitry, or the like, may be arranged between the signal source 105 and the respective first ADC core, in this example the first ADC cores 110, 120. For example, each of the first ADC cores 110, 120 may be configured to sample and/or convert the analog input signal 101 or a portion thereof, generate the first digital data 111, 121 accordingly and output the same. Further, by way of example, the plurality of first ADC cores 110,120 may be identical in layout to each other. Merely by way of example, the plurality of first ADC cores 110, 120 may be configured to operate time-interleaved. Further, in at least some examples, the plurality of first ADC cores 110, 120 may form together a time-interleaved ADC (TI-ADC) configured to operate the plurality of first ADC cores 110, 120 in parallel. The plurality of first ADC cores 110, 120 may be understood as sub-ADCs of the TI-ADC.

The apparatus 100 further comprises a second ADC core 130 configured to receive the analog input signal 101 and to generate second digital data 131 based on the analog input signal 101. That is, as illustrated in FIG. 1, the second ADC core 130 receives the same analog input signal 101 as the plurality of first ADC cores 110, 120. For example, the second ADC core 130 may have a similar or identical layout to the plurality of first ADC cores 110, 120, although this is not mandatory herein. The second ADC core 130 may be configured to sample and/or convert the analog input signal 101 or a portion thereof, generate the second digital data 131 accordingly and output the same. It is noted that although FIG. 1 illustrates the second ADC core 130 to directly receive the analog input signal 101 from the signal source 105, further elements, such as a buffer, a circuitry, or the like, may be arranged between the signal source 105 and the second ADC core 130. In at least some examples, the second ADC core 130 may be configured to sample and/or convert the analog input signal 101 at a sampling rate that is reduced compared to that of the plurality of first ADC cores 110, 120. Further, for example, the apparatus 100 may be configured to align, over time, the second digital data 131 with the first digital data 111, 121 of each of the plurality of first ADC cores 110, 120. In addition, by way of example, the apparatus 100 may be configured to vary, over time, a sampling phase of the second ADC core 130 to align, over time, the second digital data 131 with the first digital data 111, 121 of each of the plurality of first ADC cores 110, 120. As will be described further below, the second ADC core 130, and particularly the second digital data 131, may be used for correcting the first digital data 111, 121 generated by the plurality of first ADC cores 110, 120.

Further, the apparatus 100 comprises a plurality of correction circuits 140, 150 each coupled to a respective one of the plurality of first ADC cores 110, 120. Thereby, the plurality of correction circuits 140, 150 is configured to receive at least the second digital data 131 and to modify the respective first digital data 111, 121 based on the second digital data 131. In general, plurality of correction circuits 140, 150 may be configured to correct the respective first digital data 111, 121 based on the second digital data 131 and generate and/or output correspondingly corrected digital output data 141, 151. It is noted that although FIG. 1 illustrates only two correction circuits 140, 150, the number of correction circuits is not limited herein, and the plurality of correction circuits may comprise more than two. In general, the plurality of corrections circuits may comprise M correction circuits with M>1. In at least some embodiments, the number of correction circuits may comply with the number of first ADC cores. Thereby, a respective one of the plurality of correction circuits 140, 150 may be coupled to each of the plurality of first ADC cores 110, 120. Further, for example, the plurality of correction circuits 140, 150 may be in a one-to-one correspondence with the plurality of first ADC cores 110, 120. In other words, each first ADC core 110, 120 may have a dedicated correction circuit 140, 150 associated with it. It is noted, however, that the plurality of correction circuits 140, 150 may be identical in layout to each other such that the one-to-one correspondence refers basically to the number of correction circuits to be provided for a corresponding number of first ADC cores 110, 120 and not to their individual layout. However, it is to be noted that in some examples, not each first ADC core may be provided with a dedicated correction circuit. In other words, only a sub-set (i.e., not all) of the plurality of first ADC cores may be coupled to a dedicated (corresponding) correction circuit.

In at least some examples, at least one of the plurality of correction circuits 140, 150 may be further configured to determine respective correction data for the respective first digital data 111, 121 based on a difference between output of the respective correction circuit 140, 150 and the second digital data 131, and modify the respective first digital data 111, 121 based on the respective correction data. As used herein, the correction data may be denoted by q^{(p)}, where p denotes an index of the individual first ADC cores. Further, by way of example, the at least one of the plurality of correction circuits 140, 150 may be configured to subtract the respective correction data q^{(p)} from the respective first digital data 111, 121. Further, for example, the at least one of the plurality of correction circuits 140, 150 may be configured to determine the respective correction data q^{(p)} for a first sample of the respective first digital data 111, 121 by updating the respective correction data q^{(p)} for a second sample of the respective first digital data 111, 121 based on the difference between the output of the respective correction circuit 140, 150 and the second digital data 131, wherein the second sample precedes the first sample. In other words, as described above, the second ADC core 130 may be configured to sample the analog input signal 101 at a rate that is reduced compared to the plurality of first ADC cores 110, 120. Further, as described above, the apparatus may be (e.g., comprise corresponding control circuitry) configured to vary, over time, the sampling rate of the second ADC core 130 to align, over time, the second digital data 131, e.g. the samples, with the first digital data 111, 121, e.g. the samples, of each of the plurality of first ADC cores 110, 120. Thereby, each sample of the second ADC core 130 may be used as a reference for the respective correction circuit 140, 150 of the corresponding first ADC core 110, 120 the sample of which is aligned the sample of the second ADC core 130. Further, in at least some examples, the apparatus 100 may be configured to execute each of the plurality of correction circuits 140, 150 for noise reduction when the second digital data 131 is aligned with the first digital data 111, 121 of the corresponding one of the plurality of first ADC cores 110, 120.

Although not illustrated in FIG. 1, in at least some examples, the apparatus 100 may be further (e.g., comprise corresponding processing circuitry) configured to combine the corrected digital output data 141, 151 of at least part of the plurality of correction circuits 140, 150 to generate correspondingly combined corrected digital output data representing a digital conversion of the analog input signal 101 that is corrected with respect to digital output data that would directly combine the first digital data 111, 121 of the first ADC cores 110, 120.

Still referring to FIG. 1, an exemplary operation of the apparatus 100 will now be described.

Accordingly, in operation, the plurality of first ADC cores 110, 120 may cause, e.g. inherently to their design, the first digital data 111, 121 to deviate from desired digital data and/or a desired digital signal in terms of, for example, data quality or signal quality, or the like. For example, at least part of the plurality of first ADC cores 110, 120 may comprise one or more noise sources that contribute to the deviation from the desired digital data and/or desired digital signal. Accordingly, by way of example, one or more of components of the first ADC cores 110, 120 may cause noise and/or suffer from noise, e.g. flicker noise, or the like. Merely by way of example, at least one of the plurality of first ADC core 110, 120 may comprise one or more comparators or other components, which may suffer from noise, flicker noise, or the like. For example, such noise may have a power spectrum expressed by N(f)∝1/f^{α}. In operation, this low frequency noise may manifest itself as a variation, which may also be referred to as wander, of a measured average value, which may also be referred to as DC, over time. Since the individual noise sources of the plurality of first ADC cores 110, 120 are uncorrelated amongst themselves, they may appear as noise around multiples of a clock frequency f_{c} of the first ADC cores 110, 120. It is to be noted that the second ADC core 130 may cause noise at least similar to each of the plurality of first ADC cores 110, 120.

Likewise, in operation, any further component of the apparatus 100 or coupled thereto in addition to the plurality of first ADC cores 110, 120, such as a buffer, circuitry, or the like, may additionally form a noise source and additionally contribute to the deviation of the first digital data 111, 121 from the desired digital data and/or signal. For example, one such further component, e.g. buffer, circuitry, etc., may manifest itself as a single 1/f^{α} noise source centered around 0 Hz. If B such further elements, e.g. buffers, circuits, etc., were used, there may also be a noise component at multiples of

$$f - \frac{Fs}{B} ,$$

with Fs=NF_{c} denoting an aggregate sampling rate of the plurality of first ADC cores 110, 120 and Tₛ=1/Fₛ denoting a corresponding sampling period.

It is to be noted that the analog input signal 101 to be converted may have spectral content at one or more of the multiples of the clock frequency f_{c} of the first ADC cores 110, 120. Therefore, if an attempt were made to correct the above-mentioned noise, wander, etc. by setting the above-mentioned average value to e.g. zero for each of the plurality of first ADC cores 110, 120, part of the spectrum content of the analog input signal 101, e.g. part of the spectral content located at multiples of the clock frequency f_{c} of the first ADC cores 110, 120, might also be removed. Another approach for low frequency (e.g. 1/f^{α}) noise, correction in analog-to-digital conversion is autozeroing, where some of the conversion time of the plurality of first ADC cores 110, 120 is reserved to short components, e.g. comparators, thereof, measure the above-mentioned average value and cancel it. However, a drawback of this autozeroing approach is that the first ADC cores take longer to convert and hence the conversion is slowed down.

In comparison to the conventional analog-to-digital conversion, particularly the conventional autozeroing approach, the apparatus 100 described herein allows to improve analog-to-digital conversion. For this, the apparatus 100 is configured to use the second ADC core 131, and particularly its second digital data 131, as a reference for the correction of the first digital data 111, 121 of the plurality of first ADC cores 110, 120 by the plurality of correction circuits 140, 150. As the second ADC core 131 also receives the analog input signal 101, the plurality of correction circuits 140, 150 using its second digital data 131 as a reference does not remove part of the input signal 101. In other words, the apparatus 100 allows to at least partially remove noise from the first digital data 111, 121 without removing part of the analog input signal 101.

The above description of the apparatus 100 described herein may also be illustrated mathematically, as shown in the following.

Accordingly, in at least some examples, the correction data q^{(p)} to be applied to the first digital data 111, 121 of the corresponding one p of the plurality of first ADC cores 110, 120 may be given by the following mathematical expression:

$${q}^{( p )} ( n ) = {q}^{( p )} ( n - 1 ) + μ ( {y}^{( p )} ( n ) - {r}^{( p )} ( n ) ) , \qquad ( Eq . 1 )$$

with n denoting a sample position, y^{(p)} denoting the first digital data 111, 121 of the corresponding one of the plurality of first ADC cores 110, 120, r^{(p)} denoting the second digital data 131 of the second ADC core 130 and u denoting a step size of the plurality of correction circuits 140, 150.

As can be seen from the above Eq. 1, the apparatus 100 described herein allows to determine and/or update the correction data q^{(p)} to be applied to the first digital data 111, 121 of the corresponding one p of the plurality of first ADC cores 110, 120 independently from the input signal 101, which may be denoted by s(t) and which is not present in Eq. 1. This allows to correct the first digital data 111, 121 by applying the correction data q^{(p)} thereto, thereby not removing part of the input signal 101.

In more detail, the second ADC core 130 may be configured to sample the input signal 131 at a sampling rate

$$\frac{{F}_{S}}{N + 1} ,$$

with N denoting the number of first ADC cores 110, 120. Further, output samples of the plurality of first ADC cores 110, 120 that may be taken at times t=kTₛ may be given by the following mathematical expression:

$$y ( k ) = [ s ( k {T}_{S} ) + {ω}^{( k \% N )} ( k {T}_{S} ) ] , \qquad ( Eq . 2 )$$

with s(t) denoting the analog input signal 101 and @(p)(t) denoting the noise, e.g. flicker noise, corresponding to the individual first ADC core p, i.e. the individual first ADC core 110, 120. It is noted that k may go from 0 (zero) to infinity, so that k % N cyclically selects the first ADC cores 110, 120 from 0 to N−1. The correction data q^{(p)}, which may be a value, is subtracted from the output of each first ADC core p, i.e. each first ADC core 110, 120, such that the corrected output of the respective first ADC core may be expressed by the following mathematical expression:

$$\overline{y} ( k ) = y ( k ) - {q}^{( k \% N )} , \qquad ( Eq . 3 )$$

with q^{(p)} denoting the correction data for the first ADC core p. The samples output by the second ADC core 130, which may also be referred to reference samples, that may be taken at times t=k(N+1)Tₛ may be given by the following mathematical expression:

$$r ( k ) = [ s ( k ( N + 1 ) {T}_{S} ) + {ω}^{( r )} ( k ( N + 1 ) {T}_{S} ) ] , \qquad ( Eq . 4 )$$

with ω^{(r)}(kTₛ) denoting the noise, e.g. flicker noise, corresponding to the second ADC core 130. As described above, the apparatus 100 may be configured to align, over time, the samples of the second ADC core 130 that may be taken at time t=(nN+p)(N+1)Tₛ with the respective first ADC core p, i.e. the respective first ADC core 110, 120, since ((nN+p)(N+1))% N=p, leading to the following mathematical expression:

$${r}^{( p )} ( n ) = r ( n N + p ) . \qquad ( Eq . 5 )$$

Further, the samples of the first ADC cores 110, 120 taken at t=(nN+p)(N+1)Tₛ may be given by the following mathematical expression:

$${y}^{( p )} ( n ) = y ( ( n N + p ) ( N + 1 ) ) , \qquad ( Eq . 6 )$$

further leading to the following mathematical expression:

$${y}^{( p )} ( n ) - {r}^{( p )} ( n ) = [ {ω}^{( k \% N )} ( ( nN + p ) ( N + 1 ) {T}_{S} ) - {ω}^{( r )} ( ( nN + p ) ( N + 1 ) {T}_{S} ) ] , \qquad ( Eq . 7 )$$

which is independent from the analog input signal s(t), i.e. the analog input signal 101. The apparatus 100 may be further configured to use this error signal to drive the respective correction circuit 140, 150 that sets and/or updates the correction data q^{(p)} according to the above

$${q}^{( p )} ( n ) = {q}^{( p )} ( n - 1 ) + μ ( {y}^{( p )} ( n ) - {r}^{( p )} ( n ) ) . \qquad Eq . 1$$

Accordingly, as shown above, as the second ADC core 130 also comprises the input signal 101, the plurality of correction circuits 140, 150 does not remove the input signal 101, or mathematically expressed the input signal s(t). In other words, the above description may also be understood as that the apparatus 100, and particularly its plurality of corrections circuits 140, 150, may be configured to replace first ADC core-dependent spectral content, or noise, of the first digital data 111, 121 caused by the plurality of first ADC cores 110, 120 by second ADC core-dependent spectral content of the second digital data 131 caused by the second ADC core 130. As a result, the overall plurality of first ADC cores 110, 120 may have 1/f^{α} noise spectrum rather than a 1/(f−pF_{c})^{α} noise spectrum. This may be easily corrected if necessary.

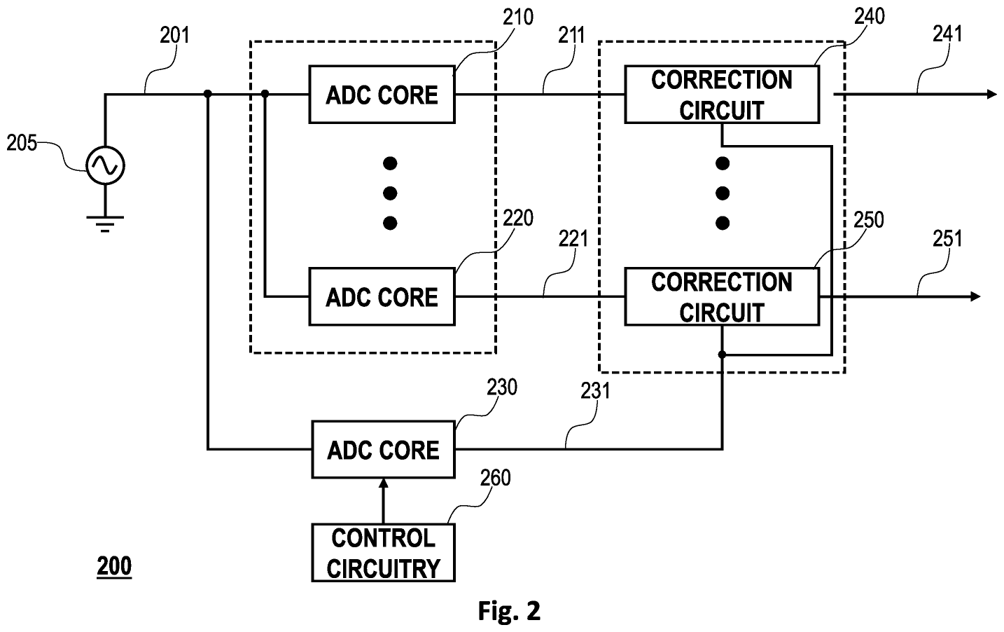

FIG. 2 illustrates another exemplary apparatus 200 for analog-to digital conversion. The apparatus 200 is based on the apparatus 100 described above and, accordingly, comprises a plurality of first ADC cores 210, 220 configured to receive an analog input signal 201, e.g. provided by a signal source 205, and to generate respective first digital data 211, 221 based on the analog input signal 201. The apparatus 200 further comprises a second ADC core 230 configured to receive the analog input signal 201 and to generate second digital data 231 based on the analog input signal 201. In addition, the apparatus 200 comprises a plurality of correction circuits 240, 250 each coupled to a respective one of the plurality of first ADC cores, wherein the plurality of correction circuits 240, 250 is configured to receive the second digital data 231 and to modify the respective first digital data 211, 221 based on the second digital data 231.

In addition, the apparatus 200 additionally comprises optional control circuitry 260 configured to align, over time, the second digital data 231 with the first digital data 211, 221 of each of the plurality of first ADC cores 210, 220, as described above. For example, the control circuitry 260 may be configured to vary, over time, the sampling phase of the second ADC core 230 to align, over time, the second digital data 231 with the first digital data 211, 221 of each of the plurality of first ADC cores 210, 220, as described above. Further, by way of example, the control circuitry 260 may be configured to receive input data indicating one or more of the sampling rate, sampling phase, clock frequency etc. of the first ADC cores 210. 220 and/or the second ADC core 230.

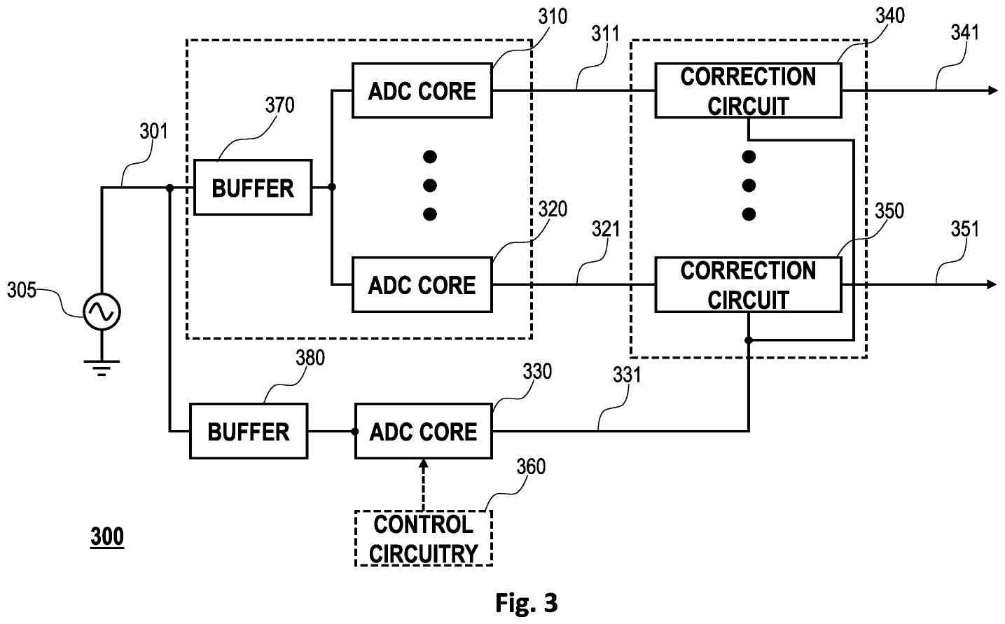

FIG. 3 illustrates another exemplary apparatus 300 for analog-to-digital conversion. The apparatus 300 is based on the apparatus 100 and/or the apparatus 200 described above and, accordingly, comprises a plurality of first ADC cores 310, 320 configured to receive an analog input signal 301, e.g. provided by a signal source 305, and to generate respective first digital data 311, 321 based on the analog input signal 301. The apparatus 300 further comprises a second ADC core 330 configured to receive the analog input signal 301 and to generate second digital data 331 based on the analog input signal 301. In addition, the apparatus 300 comprises a plurality of correction circuits 340, 350 each coupled to a respective one of the plurality of first ADC cores, wherein the plurality of correction circuits 340, 350 is configured to receive the second digital data 331 and to modify the respective first digital data 311, 321 based on the second digital data 331.

In addition, the apparatus 300 additionally comprises a first buffer 370 arranged upstream to a respective input node of each of the plurality of first ADC cores 310, 320 and configured to buffer the analog input signal 301. Further, the apparatus 300 additionally comprises a second buffer 380 arranged upstream to an input node of the second ADC core 330 and configured to buffer the analog input signal 301.

As mentioned above, in operation, the first buffer 370 may be understood as an additional noise source which may manifest itself as a single 1/f^{α} noise source centered around 0 Hz. It is noted that this applies here as the first buffer 370 is common to the complete plurality of first ADC cores 310, 320. However, as mentioned above, if B such buffers were used, e.g. one for each of the first ADC cores 310, 320, there may also be a noise component at multiples of

$$f - \frac{Fs}{B} ,$$

with Fs=NF_{c} denoting an aggregate sampling rate of the plurality of first ADC cores 310, 320 and Tₛ=1/Tₛ denoting a corresponding sampling period. It is to be noted that the second buffer 380 may cause noise at least similar to the first buffer 360.

Nevertheless, as described above, also the apparatus 300 is configured to use the second ADC core 331, and particularly its second digital data 331, as a reference for the correction of the first digital data 311, 321 of the plurality of first ADC cores 310, 320 by the plurality of correction circuits 340, 350. As the second ADC core 331 also receives the analog input signal 301, the plurality of correction circuits 340, 350 using its second digital data 331 as a reference does not remove part of the input signal 301. In other words, also the apparatus 300 allows to at least partially remove noise from the first digital data 311, 321 without removing part of the analog input signal 301.

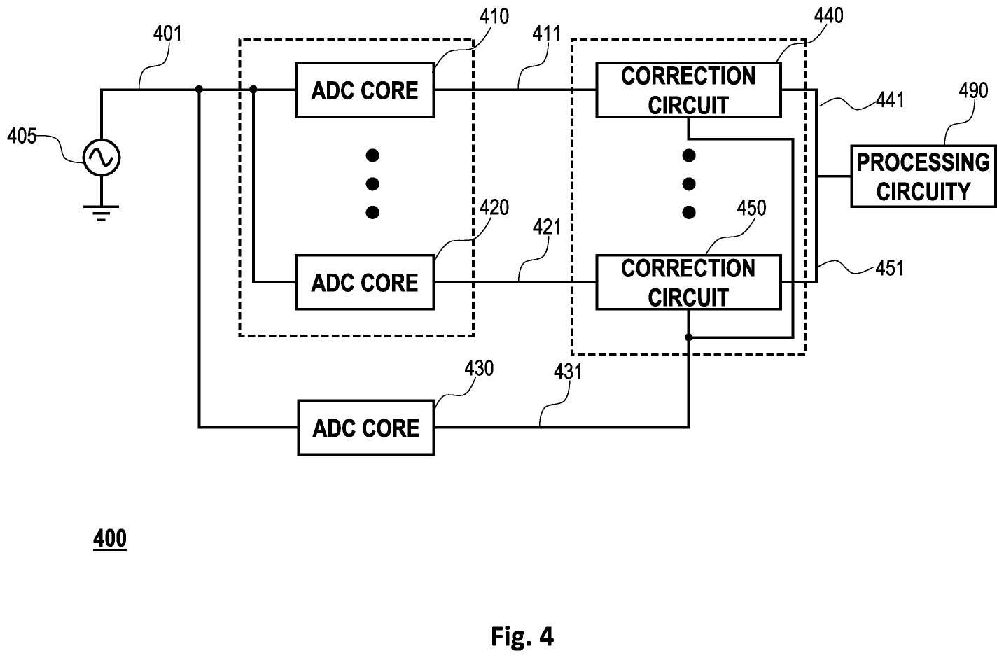

FIG. 4 illustrates another exemplary apparatus 400 for analog-to-digital conversion. The apparatus 400 is based on any one of the apparatuses 100, 200 and 300 as described above, and additionally comprises processing circuitry 490 configured to generate digital output data based on combining outputs, here denoted by 441, 451, of at least part of the plurality of correction circuits, here denoted by 440, 450.

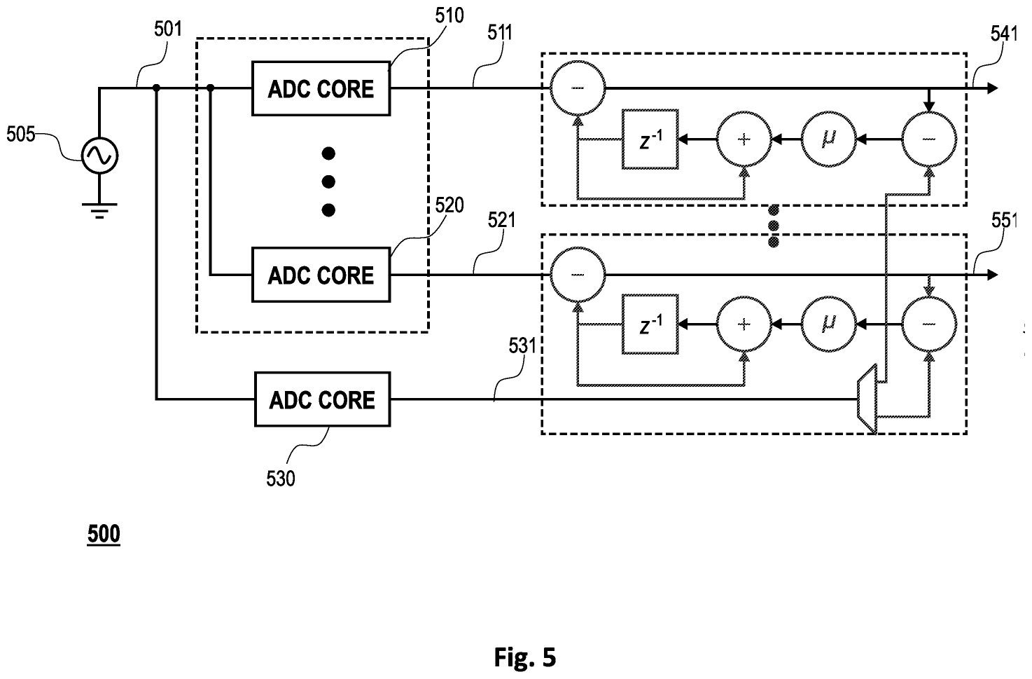

FIG. 5 illustrates an exemplary apparatus 500 for analog-to-digital conversion. This example highlights an exemplary configuration of the plurality of correction circuits 540, 550, which may be applied to any one of the apparatuses 100, 200, 300 and 400 described above.

In this example, each of the plurality of correction circuits 540, 550 comprises an adaptive system with a least mean squares (LMS) engine, e.g. LMS algorithm, or the like, having the above-mentioned step size u. As described above, the error signal y^{(p)}(n)−r^{(p)}(n)=[ω(p)((nN+p)(N+1)Tₛ)−ω^{(r)}((nN+p)(N+1)Tₛ)] (Eq. 7) drives the adaptive filter, e.g. LMS engine, that updates the correction data q^{(p)} to be applied to the first digital data 511, 521 of the corresponding one p of the plurality of first ADC cores 510, 520 as q^{(p)}(n)=q^{(p)}(n−1)+u(y^{(p)}(n)−r^{(p)}(n)) (Eq. 1). As described above, this allows to reduce noise from the first digital data 511, 521 without removing part of the analog input signal 501.

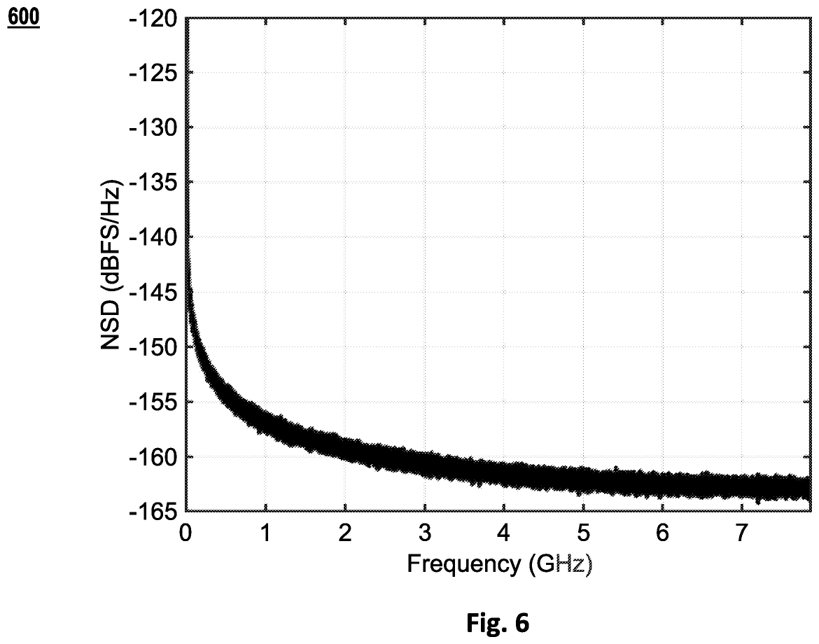

FIG. 6 illustrates in an exemplary diagram 600 the above-mentioned power spectrum of noise caused by a single one of the plurality of first ADC cores as described herein when operated. As described above, such noise may have a power spectrum that may be expressed by N(f)∝1/f^{α}. The diagram 600 according to FIG. 6 illustrates an exemplary noise spectral density (NSD) with such 1/f^{α} characteristic of the single one of the plurality of first ADC cores as described herein. As mentioned above, such noise may be inherent to the single one of the plurality of first ADC cores due to noise sources, such as a comparators or other noise-affecting component, of the first ADC cores. The abscissa of diagram 600 denotes the frequency of a signal in GHz. The ordinate denotes the NSD.

As described herein, the proposed apparatus for analog-to-digital conversion may be configured to at least partially correct the first digital data of the plurality of first ADC cores by reducing the noise illustrated in diagram 600 without removing part of the analog input signal to be converted.

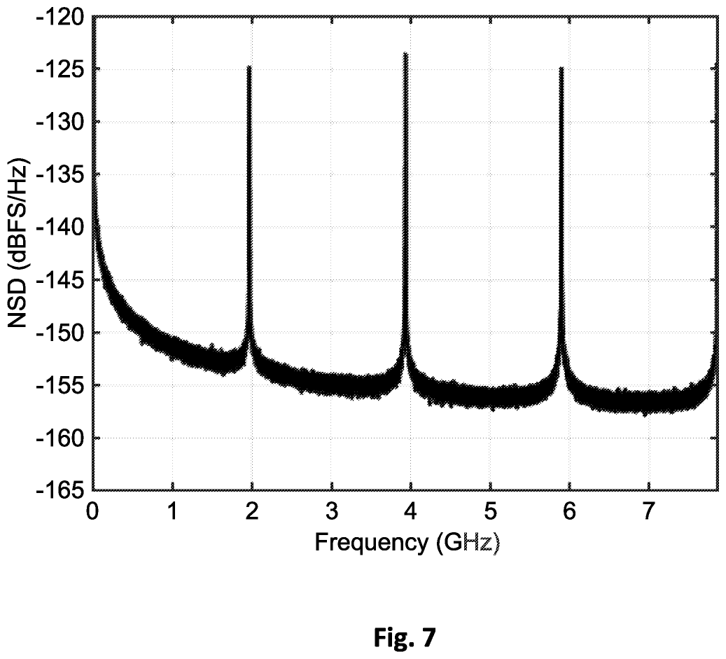

FIG. 7 illustrates in an exemplary diagram 700 a power spectrum of noise commonly caused by the plurality of first ADC cores as described herein when operated. For illustrative purposes only, the diagram 700 illustrates such power spectrum as NSD for an exemplary number of eight first ADC cores and one buffer, such as the first buffer 370 illustrated in FIG. 3.

Further, by way of example, diagram 700 illustrates the power spectrum for operation of the plurality of the first ADC cores at an aggregate sampling rate of 15.73 GSPS. The abscissa of diagram 600 denotes the frequency of a signal in GHz. The ordinate denotes the NSD.

As described herein, the proposed apparatus for analog-to-digital conversion may be configured to at least partially correct the first digital data of the plurality of first ADC cores by reducing the noise illustrated in diagram 700 without removing part of the analog input signal to be converted.

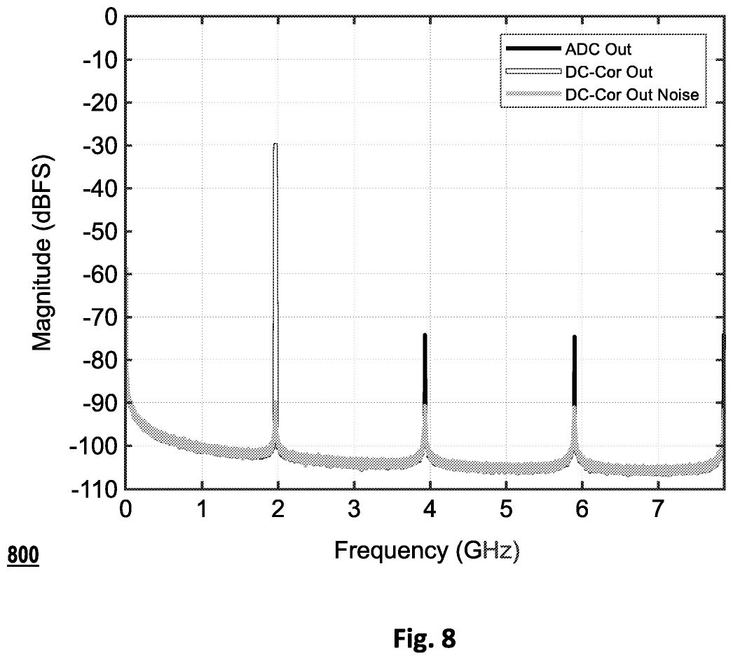

FIG. 8 illustrates in an exemplary diagram 800 a spectrum of the plurality of first ADC cores as described herein. In particular, diagram 800 illustrates output of the plurality of first ADC cores as described herein to a continuous-wave (CW) input before and after the correction by the plurality of correction circuits as described herein. The abscissa of diagram 800 denotes the frequency of a signal in GHz. The ordinate denotes a magnitude of the signal in the unit dBFS. Further, the diagram 800 includes a legend indicating three different lines with corresponding labels. A first line labeled “ADC Out” indicates the output of the first ADC cores, i.e. the first digital data as described herein. A second line labeled “DC-Cor Out” indicates the output of the correction circuits as described herein. A third line labeled “DC-Cor Out Noise” indicates the difference between the input signal and the output of the correction circuits.

It is noted that the input signal coincides with the clock frequency of the first ADC cores. Further, it is noted that, for illustrative purposes only, diagram 800 illustrates the spectrum for an exemplary number of eight first ADC cores operated at an aggregate sampling rate of 15.73 GSPS.

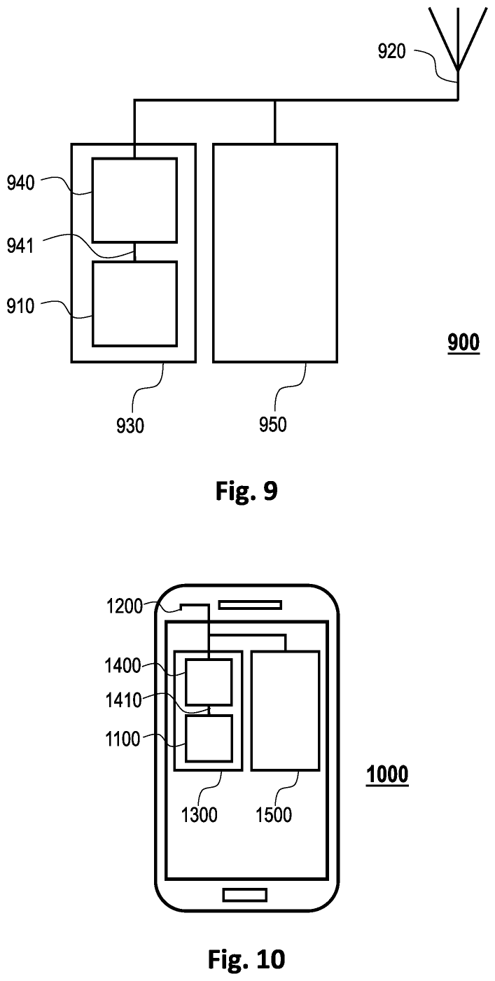

An example of an implementation using analog-to-digital conversion according to one or more aspects of the architecture described above in connection with FIGS. 1 to 8 or one or more examples described above in connection with FIGS. 1 to 8 is illustrated in FIG. 9. FIG. 9 schematically illustrates an example of a radio base station 900 (e.g., for a femtocell, a picocell, a microcell or a macrocell) comprising an apparatus for analog-to-digital conversion as described herein.

The base station 900 comprises at least one antenna element 920. A receiver 930 of the base station 900 comprises the apparatus 910 and is coupled to the antenna element 920. The receiver 930 may be coupled to the antenna element 920 via one or more intermediate elements such as one or more of a signal line, a filter, etc.

The receiver 930 additionally comprises analog circuitry 940 coupled to the apparatus 910. The analog circuitry 940 is configured to supply an analog input signal 941 to an input node of the apparatus 910. The analog circuitry 940 may comprise various elements such as one or more of a Low-Noise Amplifier (LNA), a filter, a down-converter (mixer), ElectroStatic Discharge (ESD) protection circuitry, an attenuator etc. For example, the analog circuitry 940 may be configured to generate the analog input signal 941 based on a RF receive signal received from the antenna element 920 or another antenna element (not illustrated) of the base station 920.

Additionally, the base station 900 comprises a transmitter 950 configured to generate a RF transmit signal. The transmitter 950 may use the antenna element 920 or another antenna element (not illustrated) of the base station 900 for radiating the RF transmit signal to the environment. For example, the transmitter 950 may be coupled to the antenna element 920 via one or more intermediate elements such as a filter, an up-converter (mixer) or a Power Amplifier (PA).

To this end, a base station with improved signal processing may be provided allowing the base station to achieve, for example, increased linearity, increased bandwidth, increase noise performance, lower power consumption and/or better scalability.

The base station 900 may comprise further elements such as, e.g., an application processor, a baseband processor, memory, a network controller, a user interface, power management circuitry, a satellite navigation receiver, a network interface controller or power tee circuitry.

In some aspects, the application processor may include one or more Central Processing Unit (CPU) cores and one or more of cache memory, a Low-DropOut (LDO) voltage regulator, interrupt controllers, serial interfaces such as Serial Peripheral Interface (SPI), Inter-Integrated Circuit (I2C) or universal programmable serial interface module, Real Time Clock (RTC), timer-counters including interval and watchdog timers, general purpose Input-Output (IO), memory card controllers such as Secure Digital (SD)/MultiMedia Card (MMC) or similar, Universal Serial Bus (USB) interfaces, Mobile Industry Processor Interface Alliance (MIPI) interfaces and Joint Test Access Group (JTAG) test access ports.

In some aspects, the baseband processor may be implemented, for example, as a solder-down substrate including one or more integrated circuits, a single packaged integrated circuit soldered to a main circuit board or a multi-chip module containing two or more integrated circuits.

In some aspects, the memory may include one or more of volatile memory including Dynamic Random Access Memory (DRAM) and/or Synchronous Dynamic Random Access Memory (SDRAM), and Non-Volatile Memory (NVM) including high-speed electrically erasable memory (commonly referred to as Flash memory), Phase change Random Access Memory (PRAM), Magnetoresistive Random Access Memory (MRAM) and/or a three-dimensional crosspoint (3D XPoint) memory. The memory may be implemented as one or more of solder down packaged integrated circuits, socketed memory modules and plug-in memory cards.

In some aspects, the power management (integrated) circuitry may include one or more of voltage regulators, surge protectors, power alarm detection circuitry and one or more backup power sources such as a battery or capacitor. Power alarm detection circuitry may detect one or more of brown out (under-voltage) and surge (over-voltage) conditions.

In some aspects, the power tee circuitry may provide for electrical power drawn from a network cable to provide both power supply and data connectivity to the base station using a single cable.

In some aspects, the network controller may provide connectivity to a network using a standard network interface protocol such as Ethernet. Network connectivity may be provided using a physical connection which is one of electrical (commonly referred to as copper interconnect), optical or wireless.

In some aspects, the satellite navigation receiver may include circuitry to receive and decode signals transmitted by one or more navigation satellite constellations such as the Global Positioning System (GPS), GLObalnaya NAvigatSionnaya Sputnikovaya Sistema (GLONASS), Galileo and/or BeiDou. The receiver may provide data to the application processor which may include one or more of position data or time data. The application processor may use time data to synchronize operations with other radio base stations.

In some aspects, the user interface may include one or more of physical or virtual buttons, such as a reset button, one or more indicators such as Light Emitting Diodes (LEDs) and a display screen.

Another example of an implementation using analog-to-digital conversion according to one or more aspects of the architecture described above in connection with FIG. 1 to or one or more examples described above in connection with FIGS. 1 to 8 is illustrated in FIG. 10. FIG. 10 schematically illustrates an example of a mobile device 6000 (e.g., mobile phone, smartphone, tablet-computer, or laptop) comprising a signal processing system 6100 comprising an equalizer operatively coupled to the nonlinear signal processing circuitry and an apparatus for controlling the equalizer as described herein. It is noted that the apparatus is coupled to the equalizer.

The mobile device 1000 comprises at least one antenna element 1200. A receiver 1300 of the mobile device 1000 comprises the signal processing system 1100 and is coupled to the antenna element 1200. The receiver 1300 may be coupled to the antenna element 1200 via one or more intermediate element such as one or more of a signal line, a filter, etc.

The receiver 1300 additionally comprises analog circuitry 1400, as an example of the nonlinear signal processing circuitry coupled to the signal processing system 1100. The analog circuitry 1400 is configured to supply an analog input signal 1410 to the interface circuitry or input node of the apparatus of the signal processing system 1100. The analog circuitry 1400 may comprise various elements such as one or more of a LNA, a filter, a down-converter (mixer), ESD protection circuitry, an attenuator etc. For example, the analog circuitry 1400 may be configured to generate the analog input signal 1400 based on a RF receive signal received from the antenna element 1400 or another antenna element (not illustrated) of the mobile device 1000.

Additionally, the mobile device 1000 comprises a transmitter 1500 configured to generate a RF transmit signal. The transmitter 1500 may use the antenna element 1200 or another antenna element (not illustrated) of the mobile device 1000 for radiating the RF transmit signal to the environment. For example, the transmitter 1500 may be coupled to the antenna element 1200 via one or more intermediate elements such as a filter, an up-converter (mixer) or a PA.

To this end, a mobile device with improved analog-to-digital conversion may be provided allowing the mobile device to achieve increased linearity, increased bandwidth, increase noise performance, lower power consumption and better scalability.

The mobile device 1000 may comprise further elements such as, e.g., an application processor, a baseband processor, memory, a connectivity module, a Near Field Communication (NFC) controller, an audio driver, a camera driver, a touch screen, a display driver, sensors, removable memory, a power management integrated circuit or a smart battery.

In some aspects, the application processor may include, for example, one or more CPU cores and one or more of cache memory, LDO regulators, interrupt controllers, serial interfaces such as SPI, I2C or universal programmable serial interface module, RTC, timer-counters including interval and watchdog timers, general purpose input-output (IO), memory card controllers such as SD/MMC or similar, USB interfaces, MIPI interfaces and JTAG test access ports.

In some aspects, the baseband processor may be implemented, for example, as a solder-down substrate including one or more integrated circuits, a single packaged integrated circuit soldered to a main circuit board, and/or a multi-chip module containing two or more integrated circuits.

The wireless communication circuits using analog-to-digital conversion according to the proposed architecture or one or more of the examples described above may be configured to operate according to one of the 3rd Generation Partnership Project (3GPP)-standardized mobile communication networks or systems. The mobile or wireless communication system may correspond to, for example, a 5th Generation New Radio (5G NR), a Long-Term Evolution (LTE), an LTE-Advanced (LTE-A), High Speed Packet Access (HSPA), a Universal Mobile Telecommunication System (UMTS) or a UMTS Terrestrial Radio Access Network (UTRAN), an evolved-UTRAN (e-UTRAN), a Global System for Mobile communication (GSM), an Enhanced Data rates for GSM Evolution (EDGE) network, or a GSM/EDGE Radio Access Network (GERAN). Alternatively, the wireless communication circuits may be configured to operate according to mobile communication networks with different standards, for example, a Worldwide Inter-operability for Microwave Access (WIMAX) network IEEE 802.16 or Wireless Local Area Network (WLAN) IEEE 802.11, generally an Orthogonal Frequency Division Multiple Access (OFDMA) network, a Time Division Multiple Access (TDMA) network, a Code Division Multiple Access (CDMA) network, a Wideband-CDMA (WCDMA) network, a Frequency Division Multiple Access (FDMA) network, a Spatial Division Multiple Access (SDMA) network, etc.

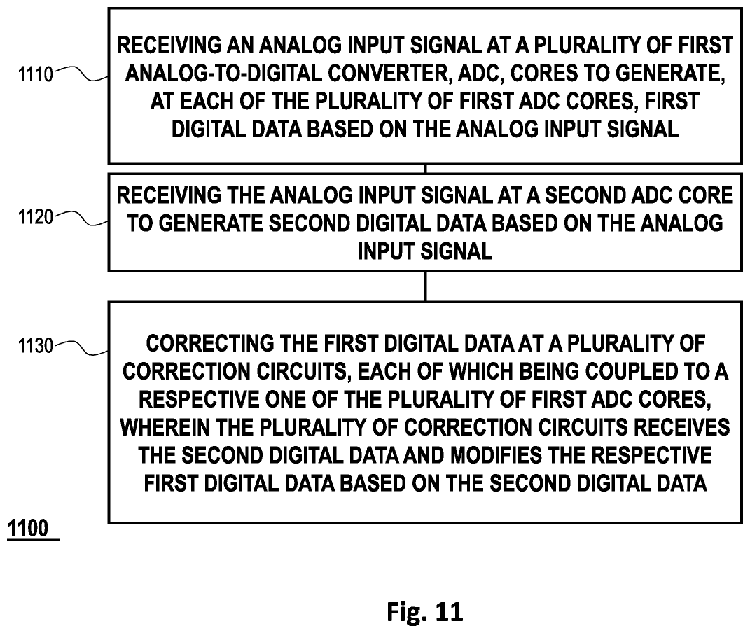

For further illustrating the analog-digital conversion described above, FIG. 11 illustrates a flowchart of a method 1100 for controlling of an equalizer. The method 1100 comprises receiving 1110 an analog input signal at a plurality of first analog-to-digital converter, ADC, cores to generate, at each of the plurality of first ADC cores, first digital data based on the analog input signal. Further, the method 1100 comprises receiving 1120 the analog input signal at a second ADC core to generate second digital data based on the analog input signal. In addition, the method 1100 comprises correcting 1130 the first digital data at a plurality of correction circuits, each of which being coupled to a respective one of the plurality of first ADC cores, wherein the plurality of correction circuits receives the second digital data and modifies the respective first digital data based on the second digital data.

The method 1100 may enable improved analog-to-digital with increased linearity, increased bandwidth, increase noise performance, lower power consumption and better scalability.

More details and aspects of the method 1100 are explained in connection with the proposed technique or one or more examples described above (e.g., FIGS. 1 to 10). The method 1100 may comprise one or more additional optional features corresponding to one or more aspects of the proposed technique or one or more examples described above.

Although the examples of FIGS. 1 to 10 are illustrated as single-ended implementations, it is to be noted that one or more components of these examples may be implemented differential as well. For example, the apparatus described herein may be integrated in the equalizer.

The examples described herein may be summarized as follows:

An example (e.g. example 1) relates to an apparatus for analog-to-digital conversion, comprising:
a plurality of first analog-to-digital converter, ADC, cores configured to receive an analog input signal and to generate respective first digital data based on the analog input signal;
a second ADC core configured to receive the analog input signal and to generate second digital data based on the analog input signal; and
a plurality of correction circuits each coupled to a respective one of the plurality of first ADC cores, wherein the plurality of correction circuits is configured to receive the second digital data and to modify the respective first digital data based on the second digital data.

Another example (e.g. example 2) relates to a previous example (e.g. example 1), wherein at least one of the plurality of correction circuits is configured to:
determine respective correction data for the respective first digital data based on a difference between output of the respective correction circuit and the second digital data; and modify the respective first digital data based on the respective correction data.

Another example (e.g. example 3) relates to a previous example (e.g. one of the examples 1 or 2), wherein the at least one of the plurality of correction circuits is configured to subtract the respective correction data from the respective first digital data.

Another example (e.g. example 4) relates to a previous example (e.g. one of the examples 2 or 3), wherein the at least one of the plurality of correction circuits is configured to determine the respective correction data for a first sample of the respective first digital data by updating the respective correction data for a second sample of the respective first digital data based on the difference between the respective first digital data and the second data, the second sample preceding the first sample.

Another example (e.g. example 5) relates to a previous example (e.g. one of the examples 2 to 4), wherein the correction data q^{(p)} to be applied to the first digital data of the corresponding one p of the plurality of first ADC cores is given by:

$${q}^{( p )} ( n ) = {q}^{( p )} ( n - 1 ) + μ ( {y}^{( p )} ( n ) - {r}^{( p )} ( n ) ) ,$$

with n denoting a sample position, y^{(p)} denoting the first digital data of the corresponding one of the plurality of first ADC cores, r^{(p)} denoting the second digital data of the second ADC core and u denoting a step size of the plurality of correction circuits.

Another example (e.g. example 6) relates to a previous example (e.g. one of the examples 1 to 5), wherein the second ADC core is configured to sample the analog input signal at a sampling rate that is reduced compared to that of the plurality of first ADC cores.

Another example (e.g. example 7) relates to a previous example (e.g. one of the examples 1 to 6), further comprising control circuitry configured to align, over time, the second digital data with the first digital data of each of the plurality of first ADC cores.

Another example (e.g. example 8) relates to a previous example (e.g. one of the examples 1 to 7), further comprising control circuitry configured to vary, over time, a sampling phase of the second ADC core to align, over time, the second digital data with the first digital data of each of the plurality of first ADC cores.

Another example (e.g. example 9) relates to a previous example (e.g. one of the examples 1 to 8), further configured to execute each of the plurality of correction circuits for noise reduction when the second digital data is aligned with the first digital data of the corresponding one of the plurality of first ADC cores.

Another example (e.g. example 10) relates to a previous example (e.g. one of the examples 1 to 9), wherein a respective one of the plurality of correction circuits is coupled to each of the plurality of first ADC cores.

Another example (e.g. example 11) relates to a previous example (e.g. one of the examples 1 to 10), wherein the plurality of correction circuits is in a one-to-one correspondence with the plurality of first ADC cores.

Another example (e.g. example 12) relates to a previous example (e.g. one of the examples 1 to 11), wherein the plurality of correction circuits is configured to replace first ADC coredependent spectral content of the first digital data caused by the plurality of first ADC cores by second ADC core-dependent spectral content of the second digital data caused by the second ADC core.

Another example (e.g. example 13) relates to a previous example (e.g. one of the examples 1 to 12), wherein the plurality of correction circuits is configured to determine, based on the second digital data, spectral content to be removed from the first digital data.

Another example (e.g. example 14) relates to a previous example (e.g. one of the examples 1 to 13), further comprising a first buffer arranged upstream to a respective input node of each of the plurality of first ADC cores and configured to buffer the analog input signal.

Another example (e.g. example 15) relates to a previous example (e.g. one of the examples 1 to 14), further comprising a second buffer arranged upstream to an input node of the second ADC core and configured to buffer the analog input signal.

Another example (e.g. example 16) relates to a previous example (e.g. one of the examples 1 to 15), wherein the plurality of first ADC cores is identical in layout to each other.

Another example (e.g. example 17) relates to a previous example (e.g. one of the examples 1 to 16), wherein the second ADC core is identical in layout to the plurality of first ADC cores.

Another example (e.g. example 18) relates to a previous example (e.g. one of the examples 1 to 17), wherein the plurality of first ADC cores is configured to operate time-interleaved.

Another example (e.g. example 19) relates to a previous example (e.g. one of the examples 1 to 18), further comprising processing circuitry configured to generate digital output data based on combining outputs of at least part of the plurality of correction circuits.

Another example (e.g. example 20) relates to a receiver, comprising:
an apparatus for analog-to-digital conversion according to any one of examples 1 to 19; and
analog circuitry coupled to the apparatus for analog-to-digital conversion and configured to supply the analog input signal to the apparatus for analog-to-digital conversion.

Another example (e.g. example 21) relates to a previous example (e.g. example 20), wherein the analog circuitry is configured to generate the analog input signal based on a radio frequency receive signal.

Another example (e.g. example 22) relates to a base station, comprising:
a receiver according to example 20 or 21; and
a transmitter configured to generate a radio frequency transmit signal.

Another example (e.g. example 23) relates to a previous example (e.g. example 22), further comprising at least one antenna coupled to at least one of the receiver and the transmitter.

Another example (e.g. example 24) relates to a mobile device, comprising:
a receiver according to example 20 or 21; and
a transmitter configured to generate a radio frequency transmit signal.

Another example (e.g. example 25) relates to a previous example (e.g. example 24), further comprising at least one antenna element coupled to at least one of the receiver and the transmitter.

Another example (e.g. example 26) relates to a method for analog-to-digital conversion, the method comprising:
receiving an analog input signal at a plurality of first analog-to-digital converter, ADC, cores to generate, at each of the plurality of first ADC cores, first digital data based on the analog input signal;
receiving the analog input signal at a second ADC core to generate second digital data based on the analog input signal; and
correcting the first digital data at a plurality of correction circuits, each of which being coupled to a respective one of the plurality of first ADC cores, wherein the plurality of correction circuits receives the second digital data and modifies the respective first digital data based on the second digital data.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. An apparatus for analog-to-digital conversion, comprising:
a plurality of first analog-to-digital converter, ADC, cores configured to receive an analog input signal and to generate respective first digital data based on the analog input signal;
a second ADC core configured to receive the analog input signal and to generate second digital data based on the analog input signal; and
a plurality of correction circuits each coupled to a respective one of the plurality of first ADC cores, wherein the plurality of correction circuits is configured to receive the second digital data and to modify the respective first digital data based on the second digital data.

2. The apparatus of claim 1, wherein at least one of the plurality of correction circuits is configured to:
determine respective correction data for the respective first digital data based on a difference between output of the respective correction circuit and the second digital data; and
modify the respective first digital data based on the respective correction data.

3. The apparatus of claim 2, wherein the at least one of the plurality of correction circuits is configured to subtract the respective correction data from the respective first digital data.

4. The apparatus of claim 2, wherein the at least one of the plurality of correction circuits is configured to determine the respective correction data for a first sample of the respective first digital data by updating the respective correction data for a second sample of the respective first digital data based on the difference between the respective first digital data and the second data, the second sample preceding the first sample.

5. The apparatus of claim 2, wherein the correction data q^{(p)} to be applied to the first digital data of the corresponding one p of the plurality of first ADC cores is given by:
$${q}^{( p )} ( n ) = {q}^{( p )} ( n - 1 ) + μ ( {y}^{( p )} ( n ) - {r}^{( p )} ( n ) ) ,$$
with n denoting a sample position, y^{(p)} denoting the first digital data of the corresponding one of the plurality of first ADC cores, r^{(p)} denoting the second digital data of the second ADC core and u denoting a step size of the plurality of correction circuits.

6. The apparatus of claim 1, wherein the second ADC core is configured to sample the analog input signal at a sampling rate that is reduced compared to that of the plurality of first ADC cores.

7. The apparatus of claim 1, further comprising control circuitry configured to align, over time, the second digital data with the first digital data of each of the plurality of first ADC cores.

8. The apparatus of claim 1, further comprising control circuitry configured to vary, over time, a sampling phase of the second ADC core to align, over time, the second digital data with the first digital data of each of the plurality of first ADC cores.

9. The apparatus of claim 1, further configured to execute each of the plurality of correction circuits for noise reduction when the second digital data is aligned with the first digital data of the corresponding one of the plurality of first ADC cores.

10. The apparatus of claim 1, wherein a respective one of the plurality of correction circuits is coupled to each of the plurality of first ADC cores.

11. The apparatus of claim 1, wherein the plurality of correction circuits is in a one-to-one correspondence with the plurality of first ADC cores.

12. The apparatus of claim 1, wherein the plurality of correction circuits is configured to replace first ADC core-dependent spectral content of the first digital data caused by the plurality of first ADC cores by second ADC core-dependent spectral content of the second digital data caused by the second ADC core.

13. The apparatus of claim 1, wherein the plurality of correction circuits is configured to determine, based on the second digital data, spectral content to be removed from the first digital data.

14. The apparatus of claim 1, further comprising a first buffer arranged upstream to a respective input node of each of the plurality of first ADC cores and configured to buffer the analog input signal.

15. The apparatus of claim 1, further comprising a second buffer arranged upstream to an input node of the second ADC core and configured to buffer the analog input signal.

16. The apparatus of claim 1, wherein the plurality of first ADC cores is identical in layout to each other.

17. The apparatus of claim 1, wherein the second ADC core is identical in layout to the plurality of first ADC cores.

18. The apparatus of claim 1, wherein the plurality of first ADC cores is configured to operate time-interleaved.

19. The apparatus of claim 1, further comprising processing circuitry configured to generate digital output data based on combining outputs of at least part of the plurality of correction circuits.

20. A receiver, comprising:
an apparatus for analog-to-digital conversion according to claim 1; and
analog circuitry coupled to the apparatus for analog-to-digital conversion and configured to supply the analog input signal to the apparatus for analog-to-digital conversion.

21. The receiver of claim 20, wherein the analog circuitry is configured to generate the analog input signal based on a radio frequency receive signal.

22. A base station, comprising:
a receiver according to claim 20; and
a transmitter configured to generate a radio frequency transmit signal.

23. The base station of claim 22, further comprising at least one antenna coupled to at least one of the receiver and the transmitter.

24. A method for analog-to-digital conversion, the method comprising:
receiving an analog input signal at a plurality of first analog-to-digital converter, ADC, cores to generate, at each of the plurality of first ADC cores, first digital data based on the analog input signal;
receiving the analog input signal at a second ADC core to generate second digital data based on the analog input signal; and
correcting the first digital data at a plurality of correction circuits, each of which being coupled to a respective one of the plurality of first ADC cores, wherein the plurality of correction circuits receives the second digital data and modifies the respective first digital data based on the second digital data.
